(19) United States
(12) Patent Application Publication
(10) Pub. No.: US 2008/0316715 A1
(43) Pub. Date: Dec. 25, 2008

(54) Coated Copper, Method for Inhibiting Generation of Whisker, Printed Wiring Board and Semiconductor Device

(75) Inventor: Nobuaki Fujii, Yamaguchi (JP)

Correspondence Address: THE WEBB LAW FIRM, P.C., 700 KOPPERS BUILDING, 436 SEVENTH AVENUE, PITTSBURGH, PA, 15219, US

(73) Assignee: Mitsui Mining & Smelting Co., Ltd., Shinagawa-ku (JP)

(21) Appl. No.: 11/632,796

(22) PCT Filed: Jun. 16, 2005
(86) PCT No.: PCT/JP2005/011042

§ 371 Date: Jan. 18, 2007

(30) Foreign Application Priority Data
Jul. 21, 2004 (JP) 2004-213308

(51) Int. Cl. H05K 1/09; B32B 15/20; H05K 1/18; B05D 5/12

(52) U.S. Cl. 361/748; 428/674; 427/97.3; 174/257

(57) ABSTRACT

A coated copper is provided which inhibits the growth of whiskers and is composed of a copper substrate or a copper alloy substrate, a copper-diffused tin layer formed on the surface of the substrate, and a pure tin layer formed on the surface of the copper-diffused tin layer. The thickness of the copper-diffused tin layer is 55% or more with respect to the total thickness of the copper-diffused tin layer and the pure tin layer. Further, a printed wiring board is provided having a wiring pattern of the copper substrate or the copper alloy substrate, and a semiconductor device. Accordingly, the generation of long whiskers having a length exceeding 15 μm which cause short circuits can be inhibited.

### TECHNICAL FIELD

The present invention relates to a method for inhibiting generation of whiskers on the surface of a tin-plated copper which forms wiring patterns and the like, a coated copper such as a wiring pattern which is inhibited in the growth of whiskers, a printed wiring board having such wiring pattern, and a semiconductor device.

### BACKGROUND ART

In recent years, the wiring pitch width of a printed wiring board and the like has become extremely narrow so as to mount electronic parts at a high density in an electronic instrument. At the vicinity of inner leads where a wiring pattern is formed at the narrowest width, the spacing between the wiring pattern and adjacent wiring patterns has been coming to narrower than 20 μm.

In the connecting portions of inner leads and the like, tin should be present so as to assure connection with, for example, bump electrodes formed on electronic parts. Tin forms an eutectic with gold which comes from the bump electrodes. Such tin is supplied from a tin-plated layer formed on the surface of the leads. So that, the surface of inner leads and the like is coated with a tin-plated layer.

It has been known that whiskers develop on the surface of the tin-plated layer described above. When these whiskers make a contact with adjacent wiring patterns, short circuit is brought about in the circuitry. Conventional printed wiring boards have wiring patterns with a wider width, so that short circuit has hardly been brought about by the whiskers which grow as long as 20 μm in one month. A printed wiring board which has whiskers no longer than 20 μm after one month has been considered to be a healthy board.

However, the criterion for the whiskers described above has become stricter since wiring patterns have become narrower in recent years. At present, a printed wiring board having whiskers whose length (direct distance) goes over 15 μm after it is left for three months has not been allowed to be used.

In view of the above circumstances, various methods inhibiting whiskers including a method of applying heat treatment to wiring patterns have been proposed to prevent the growth of whiskers. The fact is that such an extremely stringent requirement for inhibiting the growth of whiskers below 15 μm after three months is not fully satisfied yet.

The present inventor has carried out an investigation to satisfy the above mentioned extremely stringent requirement for whiskers, and found that the growth of whiskers was able to be greatly inhibited by forming a copper-diffused tin layer (that is, a tin layer containing copper diffused therein) and a pure tin layer in a specific thickness ratio on the surface of a copper substrate or a copper alloy substrate which serves as a wiring pattern.

In Patent Document 1 (Japanese Patent No. 3061613, which is applied as Japanese Patent Laid-Open Publication No. 2000-36521), an invention of a film carrier tape for mounting electronic parts is disclosed, where a tin-plated layer (a) containing copper diffused therein and a tin-plated layer (b) which is formed on the surface of tin-plated layer (a) and is substantially free from copper are formed on the terminal portions. Furthermore, Patent Document 1 cites Patent Document 2 (Japanese Patent Laid-Open Publication No. H5-33187). In Patent Document 2, an invention of inhibiting whiskers is described, where tin is plated in a thickness of 0.15 μm or more; the resulting tin-plated layer is heated so as to change the whole tin-plated layer into a Cu—Sn diffusion layer by diffusing copper from a copper substrate; and then, tin is plated again on the surface of the Cu—Sn diffusion layer so as to form a pure tin-plated layer having a thickness of 0.15 to 0.8 μm.

In the above described Patent Documents 1 and 2, that is, in the referenced documents 1 and 2, there is mentioned that the generation of whiskers can be inhibited by forming a copper-diffused tin layer in a given thickness; and further forming a pure tin layer having a given thickness. However, it has been found that the generation of whiskers cannot be always inhibited by forming a copper-diffused tin layer having a thickness described above and further forming a pure tin layer thereon. In other words, it is not denied that an effective method of inhibiting the generation of whiskers is certainly described in referenced documents 1 and 2, but even though the plated layers are formed in accordance with the description of referenced documents 1 and 2, the objective inhibition is not attained by the description of referenced documents 1 and 2, for example, when the limit of whiskers grown after three months is placed at 15 μm in terms of direct distance.

In particular, considering the current criterion for the growth of whiskers, namely, the limit of the growth is placed at 15 μm in terms of direct distance after three months, the methods disclosed in the above patent documents 1 and 2 have been found to be inadequate.

### Patent Document 1: Japanese Patent No. 3061613 (Japanese

### Patent Laid-Open Publication No. 2000-36521),

Patent Document 2: Japanese Patent Laid-Open Publication No. H5-33187.

### DISCLOSURE OF THE INVENTION

### Problems to be Solved by the Invention

The present inventor has studied on the generation of whiskers while placing the limit of the length of whiskers grown for three months at up to 15 μm, and confirmed that the generation of whiskers can be inhibited relatively effectively by the combination of a copper-diffused tin layer and a pure tin layer formed thereon. It has been also found that the length of whiskers grown does not depend on the absolute thicknesses of the copper-diffused tin layer and the pure tin layer, but depends on the ratio of thicknesses of the copper-diffused tin layer and the pure tin layer.

In order to suppress the growth of whiskers at 15 μm or less in terms of direct distance after three months, it is required that a copper-diffused tin layer and a pure tin layer be formed. It is further required that the thickness of the copper-diffused layer be regulated at a given value, since there is a close correlation between the thickness of the copper-diffused tin layer and the length of whiskers grown with respect to the total thickness of these layers.

Therefore, it is an object of the present invention to provide a coated copper in which the formation of long whiskers is inhibited, a method for inhibiting the growth of long whiskers, a printed wiring board having a wiring pattern formed from the coated copper, and a semiconductor device. In particular, it is an object of the present invention to provide a coated copper in which the formation of whiskers is inhibited in such a manner that the length of the whiskers grown after three months is limited at 15 μm or less, a method for inhibiting the growth of such long whiskers, a printed wiring board having a wiring pattern formed from the coated copper, and a semiconductor device.

### Means for Solving the Problems

The coated copper according to the present invention comprises a copper substrate or a copper alloy substrate, a copper-diffused tin layer formed on the surface of the substrate, and a pure tin layer formed on the surface of the copper-diffused tin layer, wherein the thickness of the copper-diffused tin layer is 55% or more with respect to the total thickness of the copper-diffused tin layer and the pure tin layer, and the growth of whiskers is extremely inhibited.

The method for inhibiting the growth of whiskers according to the present invention is characterized in that a copper-diffused tin layer is formed on a copper substrate or a copper alloy substrate; a pure tin layer is formed on the surface of the copper-diffused tin layer; and the thickness of the copper-diffused tin layer is regulated at 55% or more with respect to the total thickness of the copper-diffused tin layer and the pure tin layer.

The printed wiring board according to the present invention has a wiring pattern formed on an insulating film and is characterized in that the wiring pattern comprises a copper substrate or a copper alloy substrate, a copper-diffused tin layer formed on the surface of the substrate, and a pure tin layer formed on the surface of the copper-diffused tin layer, and that the thickness of the copper-diffused tin layer is 55% or more with respect to the total thickness of the copper-diffused tin layer and the pure tin layer.

The semiconductor device according to the present invention is characterized in that electronic parts such as ICs are mounted on the printed wiring board as described above.

### EFFECT OF THE INVENTION

It is generally considered that the generation of whiskers and the length of whiskers grown are changed depending on various conditions, and that a variety of conditions are required to be configured in order to inhibit the generation of whiskers and the length of whiskers grown. However, according to the study of the present inventor on the generation of whiskers, the growth of whiskers is extremely inhibited by forming on a copper substrate or a copper alloy substrate a copper-diffused tin layer having a thickness of 55% or more with respect to 100% of the total thickness of the tin-plated layer, and furthermore by forming a pure tin layer on the surface of the copper-diffused tin layer and making the total thickness of the tin-plated layer to be 100%, thereby an effect can be attained such that very few whiskers having a length of 15 μm or more (the length grown after three months) with which short circuit is brought about are generated in the wiring. Furthermore, even in the case of whiskers having a length of less than 15 μm, the generation of whiskers having a length of μm or more, which have a high possibility of growing up to whiskers with a length of 15 μm or more in a short period of time, is also inhibited.

Therefore, by employing the constitution of the present invention, very few whiskers having a length as long as reaching to adjacent wiring patterns are generated even in a current printed wiring board which has an extremely narrow pitch width, whereby the insulation reliability of printed wiring boards and semiconductor devices can be greatly enhanced.

### BRIEF DESCRIPTION OF DRAWINGS

FIG. 1 is a graph showing the relationship between the number of whiskers generated which have a length of 15 μm or more and cause short circuit and the thickness ratio of the copper-diffused tin layer, also showing the relationship between the cumulative number of whiskers having a length of 5 μm or more as well as the cumulative number of whiskers having a length of 10 μm or more and the thickness ratio of the copper-diffused tin layer.

### PREFERRED EMBODIMENTS FOR CARRYING OUT THE INVENTION

Hereinafter, there will be explained specifically the coated copper of the present invention in which the growth of whiskers is extremely inhibited, the method for inhibiting the generation of whiskers, and the printed wiring board and semiconductor device which adopt the present method, focusing on the printed wiring board.

The printed wiring board of the present invention has a wiring pattern which is formed on the surface of an insulating substrate and is made of copper or copper alloy. This wiring pattern serves as a copper substrate or a copper alloy substrate for the coated copper of the present invention.

For the copper substrate or copper alloy substrate which serves as the substrate, various kinds of copper can be used, including electrolytic copper, rolled copper, vacuum deposited copper and the like. As such copper, a copper alloy containing other metals which are allowed to be incorporated into copper can be also used. Further, a copper alloy can be also used in which other metals are explicitly incorporated so as to, for example, enhance the adhesion to the insulating substrate.

There is not any limitation on the thickness of the substrate made of copper or copper alloys, but when the coated copper is a wiring pattern for a printed wiring board, the thickness of the copper substrate or copper alloy substrate which serves as the wiring pattern is generally from 5 to 70 μm. In the case of forming a still finer wiring pattern, the thickness is in the range of from 5 to 12 μm.

In the present invention, a copper-diffused tin layer is formed on the surface of the copper substrate or copper alloy substrate in order to inhibit the generation of whiskers. The copper-diffused tin layer can be formed, for example, by forming a tin-plated layer on the surface of the substrate; and diffusing copper into the tin-plated layer thus formed. Copper can be diffused into the tin-plated layer by incorporating copper in a plating bath when tin is plated, but it is preferable that a tin layer is formed on the surface of the substrate by tin-plating and the copper contained in the substrate is diffused into the tin layer. As the method of diffusing copper into the tin layer from the substrate, generally, it is preferable to employ a heating method after the tin layer is formed. The heating temperature is generally from 90 to 16° C., and preferably from 110 to 150° C. The heating time at the heating temperature in the above described range depends on the thickness of the tin layer formed, but is generally from 10 to 150 min, and preferably from 30 to 90 min. As the heating temperature becomes higher, and as the heating time becomes longer, copper diffuses into the tin layer more easily. In particular, when the heating temperature is set to be from 110 to 150° C. and the heating time is set to be from 30 to 90 min within this temperature range, a gradient of copper concentration is developed where the concentration of copper supplied by the substrate layer decreases toward the surface of the copper-diffused tin layer. That is, in the copper-diffused tin layer, the copper concentration is the highest at the side of the substrate and is the lowest at the surface of the copper-diffused tin layer. In the copper-diffused tin layer, a concentration gradient of copper is developed where the copper concentration decreases continuously from the side of the substrate to the surface of the copper-diffused tin layer.

In the copper-diffused tin layer, the growth of whiskers can be inhibited in a more convincing way by developing the concentration gradient of copper as described above.

On the surface of the copper-diffused tin layer where copper is diffused as described above, a pure tin layer is formed. The pure tin layer is substantially composed of tin, and copper does not diffuse into the pure tin layer. The pure tin layer can be formed by plating using a plating solution containing tin after the copper-diffused tin layer is formed as described above.

In the present invention, in order to inhibit the generation of whiskers, it is necessary that the thickness of the copper-diffused tin layer be 55% or more with respect to 100% of the total thickness of the copper-diffused tin layer and the pure tin layer. Particularly in the present invention, by specifying the thickness of the copper-diffused tin layer at 55 to 99% with respect to the total thickness, the growth of whiskers can be inhibited in amore convincing way. In order to inhibit the generation of whiskers, the ratio of the copper-diffused tin layer in the total thickness of the layers is quite important. When the thickness of the copper-diffused tin layer is less than 55% with respect to the total thickness, a noticeable effect of inhibiting the growth of whiskers is not exhibited. On the other hand, when the thickness of the copper-diffused tin layer exceeds 99%, it becomes difficult to form a pure tin layer having a good uniformity since the thickness of the pure tin layer becomes 1% or less and the total thickness of the layers is not so large as that described later. In addition to that, the number of fine whiskers generated is likely to increase.

The total thickness of the copper-diffused tin layer and the pure tin layer is generally from 0.2 to 1.0 μm, and preferably from about 0.3 to about 0.8 μm. Therefore, the thickness of the copper-diffused tin layer is in the range of generally from 0.11 to 0.55 μm, and preferably from 0.165 to 0.44 μm. In accordance with the thickness of the copper-diffused tin layer which is calculated as described above, the thickness of the pure tin layer is in the range of generally from 0.09 to 0.45 μm, and preferably from 0.135 to 0.36 μm.

The explanation described above shows an example where the copper-diffused tin layer and the pure tin layer are prepared separately, but the copper-diffused tin layer and the pure tin layer can be prepared together.

For instance, a tin layer having a thickness corresponding to the total thickness as described above is formed, for example, by plating; the heating temperature and the heating time are set such that a pure tin layer remains on the surface of the tin layer; and then, copper is diffused from the substrate side of the tin layer so as to form a copper-diffused tin layer while retaining a pure tin layer in which copper is not diffused on the surface of the copper-diffused tin layer; whereby a layer in which the copper-diffused tin layer and the pure tin layer are built up in this order can be formed on the surface of a copper substrate or a copper alloy substrate.

In the present invention, the thickness of the pure tin layer is measured with a coulometric thickness tester (for example, Kocour thickness tester). The total thickness of the pure tin layer and the copper-diffused tin layer is measured with a fluorescent X-ray thickness gauge. The thickness of the copper-diffused tin layer is given by subtracting the thickness of the pure tin layer as measured with a coulometric thickness tester (for example, Kocour thickness tester) from the total thickness of the pure tin layer and the copper-diffused tin layer which is measured with a fluorescent X-ray thickness gauge as described above.

By controlling the thickness of the copper-diffused tin layer at 55% or more of the total thickness of the layers in this way, the maximum length of whiskers grown for three months can be regulated at 15 μm or less. Furthermore, by controlling at 60% or more, the maximum length of whiskers generated can be regulated at 12 μm or less, and preferably 10 μm or less. When a maximum length of whiskers grown for three months is 15 μm or less, whiskers generated from an adjacent lead hardly make an electrical connection even in a high density wiring board having leads with a spacing width of 20 μm, thereby short circuit caused by electrical connection through whiskers hardly develops.

The width of wiring patterns of a printed wiring board, which is designed to meet the current requirements for high density mounting, is around 20 μm. In addition, the spacing width between these wiring patterns having such width is also around 20 μm. The tin-plated layer forms an eutectic with gold bumps which are formed on electronic parts like IC chips when the electronic parts are mounted on a printed wiring board, and thus is necessary for acquiring an electric connection with the electronic parts and the like. This plated layer made of tin is required to be formed on the tip of a lead. The present situation is that whiskers grow from the tin-plated layer thus formed, and among these whiskers, there are a large number of whiskers which have a length exceeding the width of the adjacent lead of 20 μm.

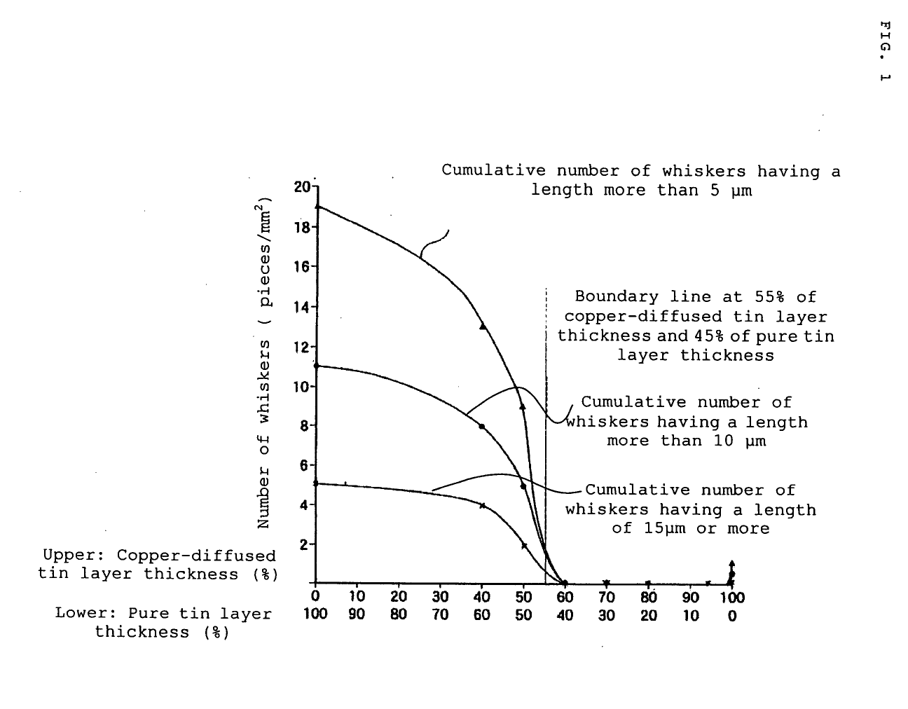

Even only one whisker grown in such a long length sometimes brings about short circuit with an adjacent lead. Although the generation of whiskers as short as a few micrometers may be allowed to some extent, it is necessary to inhibit the growth of such a long whisker as described above. When a tin-plated layer is formed on the surface of a copper substrate or a copper alloy substrate so as to cover the substrate, copper is diffused into the tin layer lying on the side of the substrate to form a copper-diffused tin layer. Furthermore, on this occasion, a pure tin layer is formed on the surface of the copper-diffused tin layer, and the thickness of the copper-diffused tin layer is set to 55% or more with respect to the total thickness (100%) of the copper-diffused tin layer and the pure tin layer, thereby the growth of whiskers is inhibited remarkably. In particular, the growth of long whiskers, for example, those exceeding 15 μm, can be inhibited. Such an effect of inhibiting the growth of whiskers as described above is not attained only by forming a tin-plated layer on the surface of a copper substrate or a copper alloy substrate, and also not attained only by forming a copper-diffused tin layer on the surface of a copper substrate or a copper alloy substrate. The effect can be attained by forming a copper-diffused tin layer having a thickness ratio of 55% or more on the surface of a copper substrate or a copper alloy substrate, and further forming a pure tin layer having a thickness ratio of 45% or less on the surface of the copper-diffused tin layer. In the present invention, the lower limit value of 55% for the thickness ratio of the copper-diffused tin layer is an extremely highly critical value for inhibiting the growth of whiskers. As shown in FIG. 1, even though a copper-diffused tin layer having a thickness ratio of less than 55% is formed, the effect of inhibiting the growth of whiskers is hardly expected, in particular, the growth of long whiskers having a length exceeding 15 μm cannot be inhibited. In order to inhibit the growth of whiskers, it is only necessary that the thickness ratio of the copper-diffused tin layer be 55% or more with respect to the total thickness of the copper-diffused tin layer and the pure tin layer. From the point of view of inhibiting the growth of whiskers, the total thickness of the copper-diffused tin layer and the pure tin layer as well as the absolute thickness of the copper-diffused tin layer or that of the pure tin layer do not exert a large effect. Therefore, in a coated layer which has a tin layer with a total thickness of a copper-diffused tin layer and a pure tin layer, for example, of 1.0 μm, when the thickness of the copper-diffused tin layer is 0.60 μm (60%) and the thickness of the pure tin layer is 0.4 μm (40%), the generation of whiskers is greatly inhibited. However, in a coated layer which has a tin layer with a total thickness of a copper-diffused tin layer and a pure tin layer, for example, of 2.0 μm, when the thickness of the copper-diffused tin layer is 0.60 μm (30%) and the thickness of the pure tin layer is 1.4 μm (70%), the growth of whiskers is not inhibited, whereby a large number of long whiskers particularly having a length of over 15 μm are generated. As described above, in order to inhibit the growth of whiskers in a manner that the length of the whiskers grown for three months is limited to 15 μm or less, it is required that the thickness ratio of the copper-diffused tin layer with respect to the total thickness of the tin layers (that is, the thickness ratio of the copper-diffused tin layer to the pure tin layer) be specified in accordance with the present invention, but not the absolute thicknesses of the copper-diffused tin layer and the pure tin layer. In this way, the length of whiskers grown for three months can be regulated at 15 μm or less in terms of direct distance, not by controlling the thickness of the copper-diffused tin layer and the thickness of the pure tin layer separately and independently, but by specifying the thickness ratio of the copper-diffused tin layer in the total thickness of the copper-diffused tin layer and the pure tin layer formed.

In the explanation described above, as a method for forming the copper-diffused tin layer and the pure tin layer which is employed in the coated copper and in the method for inhibiting the growth of whiskers according to the present invention, mainly the method is explained in which the pure tin layer is formed after the copper-diffused tin layer is formed. The present invention is not limited to this method. The copper-diffused tin layer and the pure tin layer can be also formed as follows: a tin layer is formed on the surface of a copper substrate or a copper alloy substrate, for example, by plating; the substrate is heated so as to diffuse the copper of the substrate into the plated layer formed in a manner that a copper-diffused tin layer is formed in a thickness, in the plated layer, of 55% or more with respect to 100% of the thickness of the whole plated layer, preferably in a thickness of from 60 to 99%, and that a pure tin layer is formed in a thickness of 45% or less, preferably from 1 to 40%. The heating temperature and heating time can be selected as appropriate depending on the thickness of the tin-plated layer formed; when the thickness of the tin-plated layer is from 0.3 to 0.8 μm, a copper-diffused tin layer and a pure tin layer which have thickness ratios within the ranges described above can be formed by heating at a temperature in the range of from 90 to 160° C. for example, preferably from 110 to 150° C., for from 10 to 150 min, preferably from 30 to 90 min.

The printed wiring board of the present invention has such a wiring pattern made of copper or copper alloy as described above on at least one surface of an insulating substrate. On the surface of the wiring pattern (that is, copper substrate or copper alloy substrate), the above-described copper-diffused tin layer having a thickness ratio of 55% or more and pure tin layer having a thickness ratio of 45% or less are formed.

The present invention has a high usefulness for a printed wiring board having a wiring pattern with a narrow pitch. As an insulating substrate for use in forming the wiring pattern with a narrow pitch, there may be mentioned polyimide film, polyimideamide film, polyester, polyphenylenesulfide, polyetherimide, fluororesin, liquid crystal polymer, and the like. In particular, polyimide or polyimide film which has excellent resistances against heat and chemicals is preferably used. There is not any limitation on the thickness of the insulating substrate in particular, but in the case of using an insulating substrate in a film form, the thickness is selected in the range of generally from 7 to 150 μm, preferably from 7 to 125 μm, and particularly preferably from 15 to 50 μm.

A layer of copper or copper alloy is formed on at least one surface of the insulating substrate; a photosensitive resin layer is formed on the surface of the layer of copper or copper alloy; the photosensitive resin layer is exposed to light and developed to form a desired pattern; etching is performed using the resulting pattern as a masking material so as to form a wiring pattern made of copper or copper alloy on the surface of the insulating substrate.

The resulting wiring pattern made of copper or copper alloy is used as a copper substrate or a copper alloy substrate. A copper-diffused tin layer having a thickness ratio of 55% or more is formed on the surface of the substrate, and further, a pure tin layer having a thickness ratio of 45% or less is formed on the surface of the copper-diffused tin layer.

In the case of forming the copper-diffused tin layer and the tin layer separately, these layers having given thickness ratios are formed as follows: firstly, a tin layer is formed, for example by tin-plating; a solder resist is coated in such a manner that a terminal portion is exposed; the solder resist is cured by heating, and also a copper-diffused tin layer is formed by diffusing copper into the tin layer; and then a pure tin layer is formed at the terminal portion exposed.

In place of performing tin-plating before or after the layer of solder resist is formed, the tin-plated layer is formed after the layer of solder resist is formed; copper is diffused into the tin-plated layer by heating to form the copper-diffused tin layer; and then tin-plating treatment can be performed so as to form the pure tin layer.

Further, the same tin-plating treatment as described above can be performed before the layer of solder resist is formed.

In addition, in the case of performing the tin-plating treatment one time and regulating the heating temperature and/or the heating time so as to form the copper-diffused tin layer and the pure tin layer having given thickness ratios, the tin-plated layer can be formed anytime before or after the layer of solder resist is formed. Also, heating by which the copper-diffused tin layer is formed can be performed anytime.

Furthermore, after the copper-diffused tin layer and the pure tin layer are formed, a new, extremely thin tin-plated layer can be formed on the surface of the pure tin layer. However, when such a new tin-plated layer is formed, it is necessary that the thickness ratios of the copper-diffused tin layer to the pure tin layer including the new tin layer formed be regulated within the range specified by the present invention.

The wiring pattern (that is, copper substrate or copper alloy substrate) of the printed wiring board formed as described above has the surface which is coated with the copper-diffused tin layer and the pure tin layer having specific thickness ratios, so that less whiskers are generated from the wiring pattern and that whiskers are not easy to grow. In particular, long whiskers that formed short circuit among wiring patterns hardly generate. In this way, the wiring pattern of the present invention does not bring about short circuit caused by whiskers, exhibiting an extremely high insulating reliability.

The terminals of the printed wiring board formed as described above are connected electrically to the electrodes such as bump electrodes formed on electronic parts so as to mount electronic parts such as IC chips, and then the electronic parts and their peripheries including the connected portions are sealed with resin, whereby a semiconductor device can be produced.

According to the present invention, since the surface of the wiring pattern which is a copper substrate or a copper alloy substrate is coated with the copper-diffused tin layer and the pure tin layer, the generation of whiskers from this surface can be inhibited. In particular, few long whiskers having a length exceeding 15 μm are generated. Therefore, according to the present invention, short circuit caused by whiskers does not develop among wiring patterns, and a printed wiring board having an extremely high insulating reliability is provided.

The printed wiring board of the present invention is suitable for a printed wiring board which has a wiring pattern with a wiring pattern (or lead) width of 30 μm or less and preferably from 25 to 5 μm, and a pitch width of 50 μm or less and preferably from 40 to 20 μm. The printed wiring board of the present invention includes a printed wiring board (PWB), FPC (Flexible Printed Circuit), a TAB (Tape Automated Bonding) tape, COF (Chip On Film), CSP (Chip Size Package), BGA (Ball Grid Array), μ-BGA (p-Ball Grid Array) and the like.

### INDUSTRIAL APPLICABILITY

According to the present invention, the generation of whiskers can be inhibited by altering the tin layer which covers a copper substrate or a copper alloy substrate into a copper-diffused tin layer by 55% or more from the side of the substrate. In particular, by forming the copper-diffused tin layer in this way, few long whiskers having a length exceeding 15 μm in three months generate. Therefore, the printed wiring board and semiconductor device of the present invention have no short circuit among wiring patterns caused by whiskers, exhibiting an extremely high insulating reliability.

The printed wiring board and others of the present invention and the method for producing the same will be explained in greater detail through Examples, but it should be construed that the present invention is not limited to those Examples.

### Example 1

A laminated film having a copper layer with an average thickness of 8 μm formed on the surface of a polyimide film with an average thickness of 38 μm was prepared.

A photosensitive resin layer was formed on the surface of the copper layer of the laminated film, and then the photosensitive resin layer was exposed to light and developed to form a desired pattern.

The copper layer was selectively etched using the resulting pattern as a masking material to obtain a desired wiring pattern.

A tin-plated layer having an average thickness of 0.35 μm was formed by electroless plating on the wiring pattern formed as described above. Then, the wiring pattern was heated at 115° C. for 60 min to form a copper-diffused tin-plated layer by diffusing the copper of the wiring pattern into the tin-plated layer. On the wiring pattern having the copper-diffused tin-plated layer thus formed, anew tin-plated layer having an average thickness of 0.07 μm was formed by electroless plating again. Copper did not diffuse into the new tin-plated layer thus formed, which was a pure tin layer.

The copper-diffused tin layer and the pure tin layer formed as described above were measured with a fluorescent X-ray thickness gauge (SFT3200S, manufactured by Seiko Instruments Inc.). The total thickness (100%) of the copper-diffused tin layer and the pure tin layer was 0.42 μm. The thickness of the pure tin layer as measured with a coulometric thickness tester (Kocour Thickness Tester, GC-01, manufactured by Elecfine Instruments Co., Ltd.) was 0.17 μm, which was calculated to be 40% with respect to the total thickness.

Therefore, the thickness of the copper-diffused tin layer was 0.25 μm and was calculated to be 60% with respect to the total thickness. The printed wiring board obtained as described above was left for 3 months at 25° C. The number and the length of whiskers generated from the surface were measured with an optical microscope at a magnification of 500 times. The results are shown in Table 1.

### Example 2

A laminated film having a copper layer with an average thickness of 8 μm formed on the surface of a polyimide film with an average thickness of 38 μm was prepared.

A photosensitive resin layer was formed on the surface of the copper layer of the laminated film, and then the photosensitive resin layer was exposed to light and developed to form a desired pattern.

The copper layer was selectively etched using the resulting pattern as a masking material to obtain a desired wiring pattern.

A tin-plated layer having an average thickness of 0.42 μm was formed by electroless plating on the wiring pattern formed as described above.

Then, the wiring pattern was heated at 115° C. for 60 min and the copper of the wiring pattern was diffused in 0.25 μm thick which accounted for 60% of the tin-plated layer. The total thickness of the tin-plated layer measured in a similar manner to Example 1 was 0.42 μm, and the thickness of the pure tin layer was 0.17 μm which corresponded to 40% of the total thickness. Therefore, the thickness of the copper-diffused tin layer was 0.25 μm which corresponded to 60% of the total thickness.

The printed wiring board obtained as described above was left for 3 months at 25° C. The number and the length of whiskers generated from the surface were measured with an optical microscope at a magnification of 500 times.

The results are shown in Table 1.

### Example 3

A printed wiring board was produced in a similar manner to Example 2, except that the heating temperature was changed to 125° C. and the heating time was changed to 60 min. The resulting printed wiring board was measured in a similar manner to Example 1. The total thickness of the tin-plated layer was 0.42 μm, and the thickness of the pure tin layer was 0.13 μm which corresponded to 30% of the total thickness. Therefore, the thickness of the copper-diffused tin layer was 0.29 μm which corresponded to 70% of the total thickness.

The printed wiring board obtained as described above was left for 3 months at 25° C. The number and the length of whiskers generated from the surface were measured with an optical microscope at a magnification of 500 times.

The results are shown in Table 1.

### Example 4

A printed wiring board was produced in a similar manner to Example 2, except that the heating temperature was changed to 135° C. and the heating time was changed to 60 min.

The resulting printed wiring board was measured in a similar manner to Example 1. The total thickness of the tin-plated layer was 0.42 μm, and the thickness of the pure tin layer was 0.08 μm which corresponded to 20% of the total thickness. Therefore, the thickness of the copper-diffused tin layer was 0.34 μm which corresponded to 80% of the total thickness.

The printed wiring board obtained as described above was left for 3 months at 25° C. The number and the length of whiskers generated from the surface were measured with an optical microscope at a magnification of 500 times.

The results are shown in Table 1.

### Example 5

A printed wiring board was produced in a similar manner to Example 2, except that the heating temperature was changed to 150° C. and the heating time was changed to 60 min.

The resulting printed wiring board was measured in a similar manner to Example 1. The total thickness of the tin-plated layer was 0.42 μm, and the thickness of the pure tin layer was 0.02 μm which corresponded to 5% of the total thickness. Therefore, the thickness of the copper-diffused tin layer was 0.40 μm which corresponded to 95% of the total thickness.

The printed wiring board obtained as described above was left for 3 months at 25° C. The number and the length of whiskers generated from the surface were measured with an optical microscope at a magnification of 500 times.

The results are shown in Table 1.

### Comparative Example 1

A printed wiring board was produced in a similar manner to Example 2, except that the heating temperature was changed to 100° C. and the heating time was changed to 60 min.

The resulting printed wiring board was measured in a similar manner to Example 1. The total thickness of the tin-plated layer was 0.42 μm, and the thickness of the pure tin layer was 0.21 μm which corresponded to 50% of the total thickness. Therefore, the thickness of the copper-diffused tin layer was 0.21 μm which corresponded to 50% of the total thickness.

The printed wiring board obtained as described above was left for 3 months at 25° C. The number and the length of whiskers generated from the surface were measured with an optical microscope at a magnification of 500 times.

The results are shown in Table 1.

### Comparative Example 2

A printed wiring board was produced in a similar manner to Example 2, except that the heating temperature was changed to 90° C. and the heating time was changed to 60 min.

The resulting printed wiring board was measured in a similar manner to Example 1. The total thickness of the tin-plated layer was 0.42 μm, and the thickness of the pure tin layer was 0.25 μm which corresponded to 60% of the total thickness. Therefore, the thickness of the copper-diffused tin layer was 0.17 μm which corresponded to 40% of the total thickness.

The printed wiring board obtained as described above was left for 3 months at 25° C. The number and the length of whiskers generated from the surface were measured with an optical microscope at a magnification of 500 times.

The results are shown in Table 1.

### Comparative Example 3

A printed wiring board was produced in a similar manner to Example 2, except that the heating temperature was changed to 160° C. and the heating time was changed to 80 min.

The resulting printed wiring board was measured in a similar manner to Example 1. The total thickness of the tin-plated layer was 0.42 μm, and the thickness of the pure tin layer was 0 μm which corresponded to 0% of the total thickness. Therefore, the thickness of the copper-diffused tin layer was 0.42 μm which corresponded to 100% of the total thickness.

The printed wiring board obtained as described above was left for 3 months at 25° C. The number and the length of whiskers generated from the surface were measured with an optical microscope at a magnification of 500 times.

The results are shown in Table 1.

### Comparative Example 4

A printed wiring board was produced in a similar manner to Example 2, except that the tin-plated layer was not heated and the whole tin-plated layer was used as a pure tin layer.

The resulting printed wiring board was measured in a similar manner to Example 1. The total thickness of the tin-plated layer was 0.42 μm, and the thickness of the pure tin layer was 0.42 μm which corresponded to 100% of the total thickness. Therefore, the thickness of the copper-diffused tin layer was 0 μm which accounted for 0% of the total thickness.

The printed wiring board obtained as described above was left for 3 months at 25° C. The number and the length of whiskers generated from the surface were measured with an optical microscope at a magnification of 500 times.

The results are shown in Table 1.

### Referenced Example 1

A printed wiring board was produced in a similar manner to Example 2, except that the heating temperature was changed to 160° C. and the heating time was changed to 70 min.

The resulting printed wiring board was measured in a similar manner to Example 1. The total thickness of the tin-plated layer was 0.42 μm, and the thickness of the pure tin layer was 0.002 μm which corresponded to 99.5% of the total thickness. Therefore, the thickness of the copper-diffused tin layer was 0.418 μm which corresponded to 0.5% of the total thickness.

The printed wiring board obtained as described above was left for 3 months at 25° C. The number and the length of whiskers generated from the surface were measured with an optical microscope at a magnification of 500 times.

The results are shown in Table 1.

TABLE 1

| | | | | Distribution of numbers of whiskers generated | | | | | |
|---|---|---|---|---|---|---|---|---|---|
| | | Copper- | | (pieces/mm²) | | | | | |
| | Tin-plated | diffused | Pure tin | | over 10 | over 5 | over 1 | over | |
| | layer | tin layer | layer | | μm and | μm and | μm and | 0.5 μm | |
| | thickenss | thickness | thickness | 15 μm | less than | 10 μm | 5 μm or | and 1 | 0.5 μm |
| | (μm) | (μm) (%) | (μm) (%) | or more | 15 μm | or less | less | μm or less | or less |
| Example 1 | 0.42 μm | 0.25 μm | 0.17 μm | 0 | 0 | 0 | 0 | 6 | 7 |
| | 100% | 60% | 40% | | | | | | |
| Example2 | 0.42 μm | 0.25 μm | 0.17 μm | 0 | 0 | 0 | 0 | 7 | 8 |
| | 100% | 60% | 40% | | | | | | |
| Example 3 | 0.42 μm | 0.29 μm | 0.13 μm | 0 | 0 | 0 | 1 | 5 | 7 |
| | 100% | 70% | 30% | | | | | | |
| Example 4 | 0.42 μm | 0.34 μm | 0.08 μm | 0 | 0 | 0 | 3 | 8 | 7 |
| | 100% | 80% | 20% | | | | | | |
| Example 5 | 0.42 μm | 0.40 μm | 0.02 μm | 0 | 0 | 0 | 3 | 10 | 9 |
| | 100% | 95% | 5% | | | | | | |
| Comparative | 0.42 μm | 0.21 μm | 0.21 μm | 2 | 3 | 4 | 4 | 6 | 4 |
| example 1 | 100% | 50% | 50% | | | | | | |
| Comparative | 0.42 μm | 0.17 μm | 0.25 μm | 4 | 4 | 5 | 7 | 8 | 3 |
| example 2 | 100% | 40% | 60% | | | | | | |
| Comparative | 0.42 μm | 0.42 μm | 0 μm | 0 | 1 | 1 | 4 | 9 | 9 |
| example 3 | 100% | 100% | 0% | | | | | | |
| Comparative | 0.42 μm | 0 μm | 0.42 μm | 5 | 6 | 8 | 9 | 8 | 5 |
| example 4 | 100% | 0% | 100% | | | | | | |
| Referenced | 0.42 μm | 0.418 μm | 0.002 μm | 0 | 0 | 1 | 3 | 9 | 8 |
| example 1 | 100% | 99.5% | 0.5% | | | | | | |

As is clear from Table 1 described above, by regulating the thickness of the copper-diffused tin layer at 55% or more with respect to the total thickness of the tin-plated layer, there is totally no sign of the generation of long whiskers having a length of 15 μm or more which cause short circuit among wiring patterns. Furthermore, the cumulative number of whiskers having a length exceeding 5 μm as well as the cumulative number of whiskers having a length exceeding 10 μm which are considered to be on the way to growing to long whiskers having a length exceeding 15 μm become extremely large when the thickness of the copper-diffused tin layer is 55% or less. In addition, long whiskers described above do not generate even though the thickness of the copper-diffused tin layer exceeds 99%, but as shown in Table 1, the number of short whiskers generated is likely to become large.

FIG. 1 shows the relationship between the number of whiskers generated which have a length of 15 μm or more and cause short circuit and the thickness ratio of the copper-diffused tin layer, also showing the relationship between the cumulative number of whiskers having a length of 5 μm or more as well as the cumulative number of whiskers having a length of 10 μm or more and the thickness ratio of the copper-diffused tin layer.

FIG. 1 clearly shows that few whiskers having a length of 15 μm or more are found in the region where the thickness ratio of the copper-diffused tin layer in the whole tin-plated layer is 55% or more, and that the thickness ratio of the copper-diffused tin layer at 55% has a critical significance about the generation of long whiskers. In Examples and Comparative Examples described above, in order to show clearly the generation occurrence of whiskers in accordance with the thickness ratio of the copper-diffused tin layer and the pure tin layer in the tin-plated layer, the total thickness of the tin-plated layer was fixed at 0.42 μm. Under this condition, the thickness ratio between the copper-diffused layer and the pure tin layer was changed so as to show the generation occurrence of whiskers. However, even though the total thickness of the tin-plated layer is changed as appropriate, the same effect as described above can be attained depending on the thickness ratio between the copper-diffused tin layer and the pure tin layer.

1. A coated copper, being inhibited in the growth of whiskers, comprising a copper substrate or a copper alloy substrate, a copper-diffused tin layer formed on the surface of the substrate, and a pure tin layer formed on the surface of the copper-diffused tin layer, wherein the thickness of the copper-diffused tin layer is 55% or more with respect to the total thickness of the copper-diffused tin layer and the pure tin layer.

2. The coated copper according to claim 1, wherein the total thickness of the copper-diffused tin layer and the pure tin layer is in the range of from 0.2 to 1.0 μm.

3. The coated copper according to claim 1, wherein the coated copper is a wiring pattern formed on an insulating substrate.

4. The coated copper according to claim 1, wherein the copper-diffused tin layer formed on the copper substrate or the copper alloy substrate has a continuous concentration gradient where the copper concentration in the thickness direction is higher on the side of the substrate and is lower on the side of the pure tin layer.

5. The coated copper according to claim 1, wherein the copper-diffused tin layer and the pure tin layer are formed by plating.

6. A method for inhibiting generation of whiskers, comprising forming a copper-diffused tin layer on a copper substrate or a copper alloy substrate, and forming a pure tin layer on the surface of the copper-diffused tin layer, wherein the thickness of the copper-diffused tin layer is made 55% or more with respect to the total thickness of the copper-diffused tin layer and the pure tin layer.

7. The method for inhibiting generation of whiskers according to claim 6, wherein the total thickness of the copper-diffused tin layer and the pure tin layer is in the range of from 0.2 μm to 1.0 μm.

8. The method for inhibiting generation of whiskers according to claim 6, wherein the copper-diffused tin layer formed on the copper substrate or the copper alloy substrate has a continuous concentration gradient where the copper concentration in the thickness direction is higher on the side of the substrate and is lower on the side of the pure tin layer.

9. The method for inhibiting generation of whiskers according to claim 6, wherein the copper-diffused tin layer and the pure tin layer are formed by plating.

10. A printed wiring board having a wiring pattern formed on an insulating film, wherein the wiring pattern comprises a copper substrate or a copper alloy substrate, a copper-diffused tin layer formed on the surface of the substrate, and a pure tin layer formed on the copper-diffused tin layer, and the thickness of the copper-diffused tin layer is 55% or more with respect to the total thickness of the copper-diffused tin layer and the pure tin layer.

11. The printed wiring board according to claim 10, wherein the total thickness of the copper-diffused tin layer and the pure tin layer is in the range of from 0.2 to 1.0 μm.

12. The printed wiring board according to claim 10, wherein the copper-diffused tin layer formed on the copper substrate or the copper alloy substrate has a continuous concentration gradient where the copper concentration in the thickness direction is higher on the side of the substrate and is lower on the side of the pure tin layer.

13. The printed wiring board according to claim 10, wherein the copper-diffused tin layer and the pure tin layer are formed by plating.

14. A semiconductor device comprising a printed wiring board according to claim 10 and electronic parts mounted on the printed wiring board.

15. A semiconductor device comprising a printed wiring board according to claim 11 and electronic parts mounted on the printed wiring board.

16. A semiconductor device comprising a printed wiring board according to claim 12 and electronic parts mounted on the printed wiring board.

17. A semiconductor device comprising a printed wiring board according to claim 13 and electronic parts mounted on the printed wiring board.
